(19) United States
(12) Patent Application Publication
(10) Pub. No.: US 2007/0077686 A1
(43) Pub. Date: Apr. 5, 2007

(54) PACKAGING METHOD FOR PREVENTING CHIPS FROM BEING INTERFERED AND PACKAGE STRUCTURE THEREOF

(76) Inventor: Chieh-Chia Hu, Kao-Hsiung City (TW)

Correspondence Address: NORTH AMERICA INTELLECTUAL PROPERTY CORPORATION, P.O. BOX 506, MERRIFIELD, VA, 22116, US

(21) Appl. No.: 11/459,644

(22) Filed: Jul. 25, 2006

(30) Foreign Application Priority Data
Sep. 30, 2005 (TW) 094134289

(51) Int. Cl. H01L 21/00

(52) U.S. Cl. 438/117; 257/E21.499

(57) ABSTRACT

A package structure for preventing chips from being interfered is disclosed. The package structure includes a substrate and a chip. The substrate has a metal layer with a conducting trace area and a shielding area, and a dielectric layer having a plurality of via holes formed therein. The dielectric layer is formed on a top surface of the conducting trace area. The chip is positioned on the dielectric layer with the chip electrically connected to the conducting trace area of the metal layer. The shielding area of the metal layer is connected to the chip by bending the metal layer.

### BACKGROUND OF THE INVENTION

1. Field of the Invention

The present invention relates to a packaging method for preventing chips from being interfered and a package structure thereof, and more particularly to a packaging method and a package structure that provide a high heat-dissipating effect and a metal shield effect for a chip by a metal layer of a substrate, and the metal layer is directly connected to the chip.

2. Description of the Prior Art

Since consumers' requirements of electronic products increase day by day, improving technology for semiconductor manufacture and design of high frequency chips with better functions obviously becomes an important issue in today's research. For semiconductor packaging of the high frequency chips, serious electromagnetic wave problems occur frequently due to strong electromagnetic waves generated by the high frequency chips in operation, and the electromagnetic waves are transmitted outside through the package body to cause an electromagnetic interference (EMI) problem in nearby electronic devices, and possibly reduce electrical quality and heat-dissipating efficiency of the package. It is a serious problem of the high frequency semiconductor package.

A conventional packaging method uses a metal mask to cover the package and connects the metal mask to ground to solve the EMI problem. However, the metal mask has disadvantages of high weight and expense, and causes difficulty in mass production. The conventional method obviously does not fit in with a package of low weight, low cost, and mass production.

Therefore, developing a packaging method for preventing chips from being interfered by electromagnetic waves and a package structure thereof with package requirements of heat-dissipation, low cost, and low weight is a major issue in the related research field.

### SUMMARY OF THE INVENTION

The present invention solves the technical problems by using a metal layer of a substrate with the metal layer directly connected to a chip. The present invention not only achieves a high heat-dissipating effect and a metal shield effect for the chip, but also simplifies the anti-electromagnetic wave package process of the prior art and saves costs.

To solve the technical problems mentioned above, the present invention discloses a packaging method for preventing chips from being interfered. The packaging method includes the following steps; providing a substrate where the substrate includes a metal layer with a conducting trace area and a shielding area, and a dielectric layer having a plurality of via holes formed on a top surface of the conducting trace area. Then, positioning a chip on the dielectric layer with the chip electrically connected to the conducting trace area of the metal layer, and finally bending the metal layer to connect the shielding area of the metal layer with the chip completes the process.

To solve the technical problems mentioned above, the present invention discloses a package structure for preventing chips from being interfered, and the package structure includes a substrate and a chip. The substrate has a metal layer with a conducting trace area and a shielding area, and a dielectric layer having a plurality of via holes formed therein. The dielectric layer is formed on a top surface of the conducting trace area. The chip is positioned on the dielectric layer with the chip electrically connected to the conducting trace area of the metal layer. The shielding area of the metal layer is connected to the chip by bending the metal layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional diagram of a package structure for preventing chips from being interfered before bending the metal layer according to the first embodiment of the present invention.

FIG. 2 is a cross-sectional diagram of a package structure for preventing chips from being interfered after bending the metal layer according to the first embodiment of the present invention.

FIG. 3 is an up-view diagram of a package structure for preventing chips from being interfered when the metal layer is formed on the solder mask according to the first embodiment of the present invention.

FIG. 4 is a cross-sectional diagram of a package structure for preventing chips from being interfered before bending the metal layer according to the second embodiment of the present invention.

FIG. 5 is a cross-sectional diagram of a package structure for preventing chips from being interfered after bending the metal layer according to the second embodiment of the present invention.

FIG. 6 is a flowchart of the packaging method for preventing chips from being interfered according to the present invention.

### DETAILED DESCRIPTION

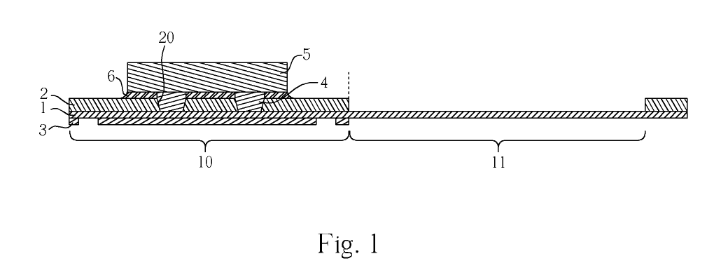

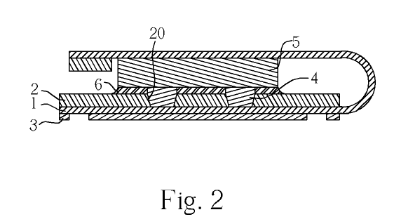

Please refer to FIG. 1 and FIG. 2. FIG. 1 and FIG. 2 are cross-sectional diagrams showing a package structure for preventing chips from being interfered before bending the metal layer and after bending the metal layer according to the first embodiment of the present invention. As shown in FIG. 1 and FIG. 2, the present invention provides a package structure for preventing chips from being interfered, in which the package structure includes a substrate and a chip 5. Preferably, the chip is a base band chip or a radio frequency (RF) chip.

The substrate includes a metal layer 1, a dielectric layer 2, and a solder mask 3. The dielectric layer 2 is a flexible polyimide substrate, and the conducting trace area of the flexible polyimide substrate can be a single layer or a dual layer according to layout electrical requirements. The metal layer 1 includes a conducting trace area 10 and a shielding area 11, and the dielectric layer 2 is formed on a top surface of the conducting trace area 10. The solder mask 3 is formed on a bottom surface of the conducting trace area 10 and the chip 5 is positioned on the dielectric layer 2.

The shielding area 11 of the metal layer 1 is connected with the chip 5 (the shielding area 11 and the chip 5 are connected with an adhesive) by bending the metal layer 1 to achieve a high heat-dissipating effect and a metal shield effect for the chip 5. In other words, the chip 5 not only spreads heat generated by itself to the shielding area 11 of the metal layer 1 to achieve a heat-dissipating effect, but also generates a metal shielding effect from the metal shielding property of the shielding area 11 to prevent interference of magnetic fields from the external environment.

In addition, the dielectric layer 2 includes a plurality of via holes 20, and the chip 5 is electrically connected to the conducting trace area 10 of the metal layer 1 through bumps 4 positioned in the via holes 20 accordingly.

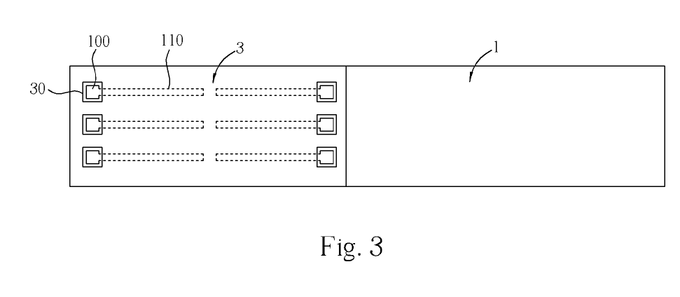

Moreover, as shown in FIG. 3, the conducting trace area 10 includes a plurality of pads 100, in which each of the pads 100 is connected to a conducting trace 110, and the solder mask 3 is utilized to reveal the pads 100.

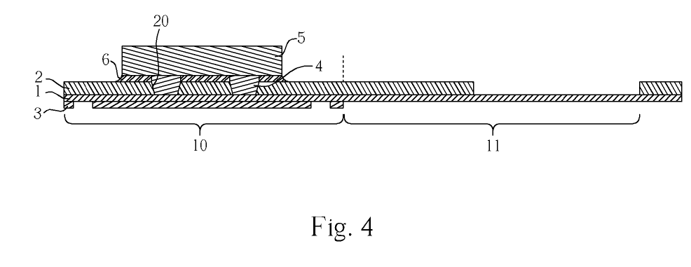

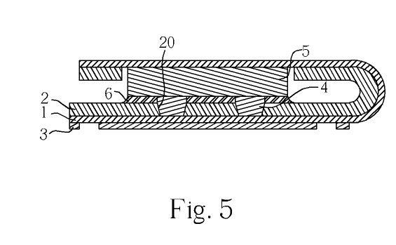

Please refer to FIG. 4 and FIG. 5. FIG. 4 and FIG. 5 are cross-sectional diagrams showing a package structure for preventing chips from being interfered before bending the metal layer and after bending the metal layer according to the second embodiment of the present invention. As shown in FIG. 4 and FIG. 5, the major difference between the first embodiment and the second embodiment is that the dielectric layer 2 is extended to a part of the top surface of the shielding area 11. Additionally, the high heat-dissipating effect and the metal shield effect can be provided for the chip 5 by bending the metal layer 1 and the partial dielectric layer 2.

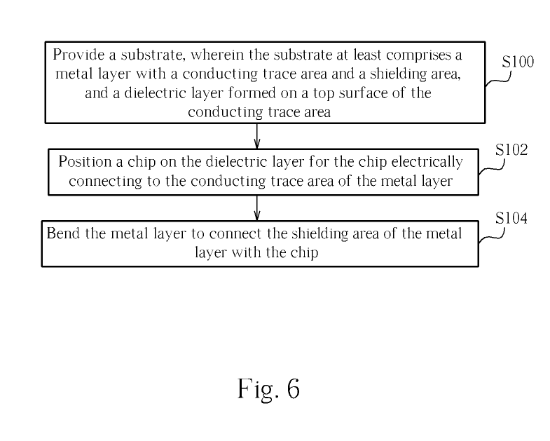

Please refer to FIG. 6. FIG. 6 is a flowchart of the packaging method for preventing chips from being interfered according to the present invention. As shown in the flowchart, the present invention provides a packaging method for preventing chips from being interfered, in which the packaging method includes the following steps: providing a substrate having a metal layer 1 with a conducting trace area 10 and a shielding area 11, and a dielectric layer 2 formed on a top surface of the conducting trace area 10 (S100). Next, a chip 5 is positioned on the dielectric layer 2 and electrically connected to the conducting trace area 10 of the metal layer 1 (S102). Finally, the metal layer 1 is bended to connect the shielding area 11 of the metal layer 1 with the chip 5 (S104).

As mentioned above, the present invention connects the shielding area 11 of the metal layer 1 to the chip 5 by bending of the metal layer 1 (or with the dielectric layer 2) of the substrate, and thus the present invention not only achieves a high heat-dissipating effect and a metal shield effect for the chip, but also simplifies the anti-electromagnetic wave package process of the prior art and saves costs.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A packaging method for preventing chips from being interfered comprising:
providing a substrate, wherein the substrate comprises a metal layer with a conducting trace area and a shielding area, and a dielectric layer formed on a top surface of the conducting trace area;
positioning a chip on the dielectric layer, wherein the chip electrically connects the conducting trace area of the metal layer; and
bending the metal layer to connect the shielding area of the metal layer with the chip.

2. The packaging method for preventing chips from being interfered of claim 1, wherein the chip is a base band chip or a radio frequency chip.

3. The packaging method for preventing chips from being interfered of claim 1, wherein the dielectric layer is a flexible polyimide substrate.

4. The packaging method for preventing chips from being interfered of claim 3, wherein the conducting trace area of the flexible polyimide substrate is a single layer or a dual layer according to layout electrical requirements.

5. The packaging method for preventing chips from being interfered of claim 1, wherein the dielectric layer comprises a plurality of via holes, and the chip is electrically connected to the conducting trace area of the metal layer through bumps positioned in the via holes accordingly.

6. The packaging method for preventing chips from being interfered of claim 1, wherein the shielding area and the chip are connected with an adhesive.

7. The packaging method for preventing chips from being interfered of claim 1 further comprising extending a part of the dielectric layer to a top surface of the shielding area.

8. The packaging method for preventing chips from being interfered of claim 7, wherein the step of bending the metal layer further comprises bending the part of the dielectric layer extending to the top surface of the shielding area.

9. The packaging method for preventing chips from being interfered of claim 1, wherein the substrate further comprises a solder mask formed on a bottom surface of the conducting trace area.

10. The packaging method for preventing chips from being interfered of claim 9, wherein the conducting trace area comprises a plurality of pads, and the solder mask is utilized to reveal the pads.

11. The packaging method for preventing chips from being interfered of claim 10, wherein the each pad is connected to a conducting trace.
